(19) United States
(12) Patent Application Publication
(10) Pub. No.: US 2016/0183519 A1
(43) Pub. Date: Jun. 30, 2016

(54) ANTIBIOTIC TREATING METHOD FOR A SAPPHIRE

(71) Applicant: CATCHER TECHNOLOGY CO., LTD., TAINAN CITY (TW)

(72) Inventors: SHENG-YI LEE, TAINAN CITY (TW); CHENG-FENG HUANG, KAOHSIUNG CITY (TW); FENG-JU LAI, TAIPEI CITY (TW); SHIH-WEI LEE, TAINAN CITY (TW)

(21) Appl. No.: 14/672,435

(22) Filed: Mar. 30, 2015

(30) Foreign Application Priority Data
Dec. 31, 2014 (TW) 103146592

(51) Int. Cl. A01N 25/08; C23C 14/14; C23C 14/48; A01N 59/16

(52) U.S. Cl. CPC A01N 25/08; A01N 59/16; C23C 14/14; C23C 14/48

(57) ABSTRACT

The instant disclosure is related to a sapphire, including a surface and a silver-containing antibiotic source, wherein the silver-containing antibiotic source forms an antibiotic film covering the surface. The instant disclosure also relates to a sapphire, including a surface, an oxide layer extending from the surface to inside of the surface, and a silver-containing antibiotic source, wherein the silver-containing antibiotic source is distributed in the oxide layer, so as to turn the oxide layer into an antibiotic layer and turn the surface into an antibiotic surface. Therefore, the sapphire can have an antibiotic to reduce bacteria proliferation issues.

### BACKGROUND OF THE INVENTION

1. Field of the Invention

The instant disclosure relates to a sapphire and antibiotic treating method for a sapphire; in particular, to a processing method for the sapphire to have antibiotic activity.

2. Description of Related Art

Sapphire mainly comprises Al₂O₃ and is superior over non-sapphire glass in the scratch-resistant aspect. Sapphire is considered an important component of touch control panels or screens for increasing durability, because scratching is no longer a problem. Sapphire is specifically suitable for screens or panels which are often touched, such as personal mobile panels or the public screens of cash dispensers.

However, these touch control screens are often touched and cannot be disinfected very well. Therefore, bacteria from the hands of people very easily proliferate, and great numbers of bacteria are found on the screen. This bacteria proliferation issue should be considered and addressed.

Therefore, the disclosure provides a new antibiotic treating method for sapphire to effectually solve the drawbacks described above.

### SUMMARY OF THE INVENTION

The objective of the instant disclosure is to provide a sapphire and an antibiotic treating method for a sapphire which can solve the bacteria proliferation issues of traditional touch control screen and improve sanitary aspects thereof.

In order to achieve the aforementioned objectives, according to an embodiment of the instant disclosure, an antibiotic treating method for a sapphire is disclosed, comprising providing a sapphire workpiece; providing a silver-containing antibiotic source; and using the silver-containing antibiotic source to perform a processing procedure to the sapphire workpiece for having an antibiotic effect.

Preferably, the processing procedure is a depositing method, such as physical vapor deposition or liquid depositing method.

Preferably, the processing procedure is a coating method.

Preferably, the processing procedure is an ion-exchange process.

Preferably, the processing procedure is an ion implantation process.

The disclosure further provides sapphire, comprising a surface; and a silver-containing antibiotic source forming an antibiotic film on the cover of the surface.

The disclosure further provides a sapphire, comprising a surface, an oxide layer extending from the surface to a portion inside the surface, and a silver-containing antibiotic source distributed in the oxide layer to transform the oxide layer as an antibiotic film, and make the surface forming an antibiotic surface.

In order to further understand the instant disclosure, the following embodiments and illustrations are provided. However, the detailed description and drawings are merely illustrative of the disclosure, rather than limiting the scope being defined by the appended claims and equivalents thereof.

### BRIEF DESCRIPTION OF THE DRAWINGS

FIG. 1A shows a flow chart of the antibiotic treating method to a sapphire of the disclosure.

FIG. 1B shows a flow chart of the antibiotic treating method to a sapphire related to a chemical solution method of the disclosure.

FIG. 1C shows a flow chart of the antibiotic treating method to a sapphire related to an immersion method of the disclosure.

FIG. 1D shows a flow chart of the antibiotic treating method to a sapphire related to a coating method of the disclosure.

FIG. 1E shows a flow chart of the antibiotic treating method to a sapphire related to an ion implantation method of the disclosure.

FIG. 2A shows a cross section view of a sapphire of the disclosure.

FIG. 2B shows a cross section view of a sapphire of another embodiment of the disclosure.

### DETAILED DESCRIPTION OF THE PREFERRED EMBODIMENTS

The aforementioned illustrations and detailed descriptions are exemplary for the purpose of further explaining the scope of the instant disclosure. Other objectives and advantages related to the instant disclosure will be illustrated in the subsequent descriptions and appended drawings.

### First Embodiment

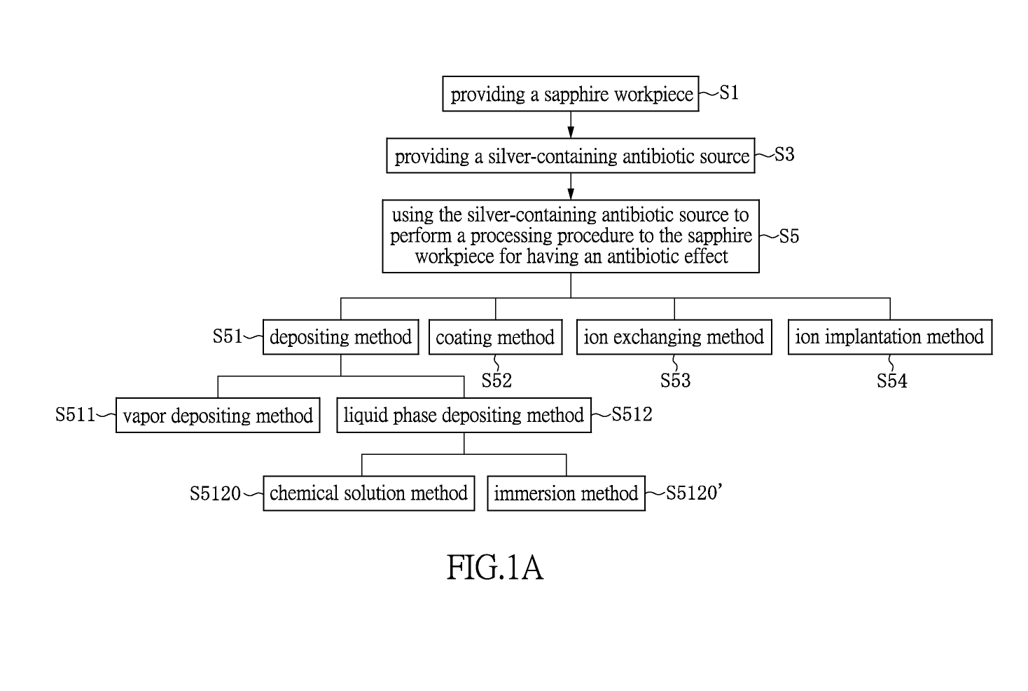

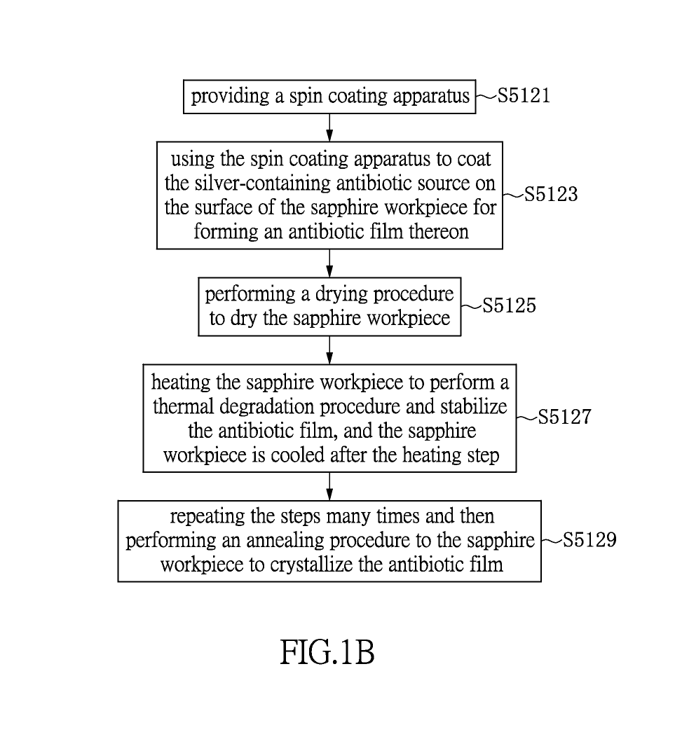

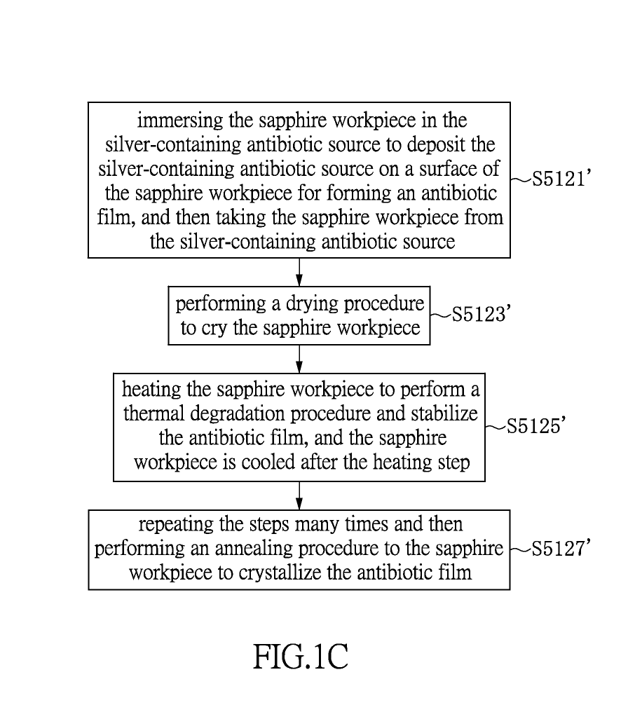

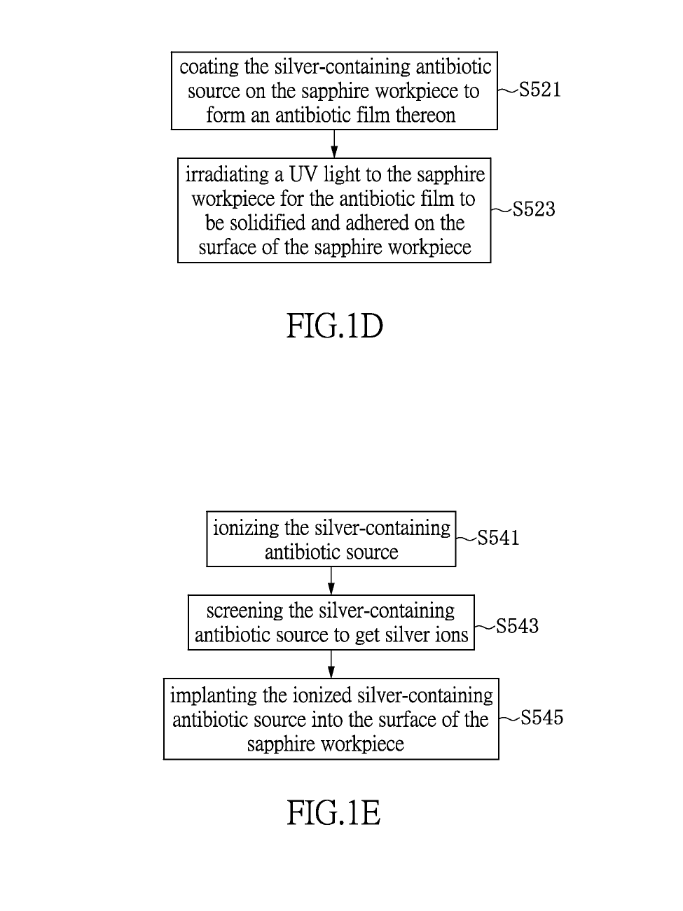

Referring to FIG. 1A, the disclosure provides an antibiotic treating method to a sapphire, comprising the following steps. In step S1, a sapphire workpiece is provided. In step S3, a silver-containing antibiotic source is provided. In step S5, the silver-containing antibiotic source is used to perform a processing procedure to the sapphire workpiece, so as to allow the sapphire workpiece to have an antibiotic/antimicrobial effect. It should be known that the sapphire workpiece is a sapphire object waiting to be processed and it usually is a sapphire substrate. However, the sapphire is not limited to a plate shaped object. In addition, the processing procedure is not limited to a specific type in the disclosure, but it can be a depositing method (step 51). Therefore, the processing procedure can include the step as follows: using the depositing method to deposit the silver-containing antibiotic source on and adhered to a surface of the sapphire workpiece.

Still referring to FIG. 1A, preferably, the depositing method (step 51) can be a vapor depositing method (step S511). For example, it can be physical vapor deposition (PVD), and preferably is sputtering. However, the disclosure is not limited thereto. The vapor deposition can also be vacuum evaporation, ion plating or plasma sprayed coating, but the disclosure is not limited thereto. The silver-containing antibiotic source (target source) can be mixture of metal oxide and silver particles, in which the metal oxide preferably is TiO₂ or Al₂O₃, and followed by using a vapor depositing method to make the silver-containing antibiotic source deposited and adhered on the surface of the sapphire workpiece. Therefore, the silver-containing antibiotic source is used to form an antibiotic film on the surface of the sapphire workpiece. The method is illustrated as follows using sputtering as an example, in which the flow chart is omitted, however details of the sputtering are not limited thereto.

Arc discharge with a large current in a vacuum environment is used to vaporize and ionize the silver-containing antibiotic source. Next, the ionized silver-containing antibiotic source is applied with an electric and magnetic field to accelerate toward the sapphire workpiece and is deposited thereon. Therefore, when the antibiotic film is formed on the surface of the sapphire workpiece, the metal oxide is deposited on the sapphire workpiece to form an oxide layer. It is noted that because sapphire mainly comprises Al₂O₃, the oxide layer can act as a substrate to increase adhesion between the antibiotic film and the sapphire workpiece. Preferably, the antibiotic film can be 1 μm thick. In a preferred example, the silver-containing antibiotic source can be selected from the group consisting of silver containing aluminum oxide, silver containing chrome oxide or a mixture thereof, and the sputtering method is performed to form the antibiotic film on the surface of the sapphire workpiece.

### Second Embodiment

Referring to FIG. 1A, the depositing method illustrated in the first embodiment can also be a liquid depositing method (step S512), and preferably is a chemical solution method (step S5120). The silver-containing antibiotic source can be silver containing aluminum oxide (AgAlO₂) with a concentration of 0.01˜0.0M, silver containing chrome oxide (AgCrO₂) or a mixture thereof and a solvent. In addition, some silver salts can be added to the silver-containing antibiotic source. The silver salt can be silver acetate, silver nitrate, silver sulfate, silver chloride, etc. The solvent preferably has a boiling point lower than 200° C. and more preferably is water, methanol, ethanol, propanol, butanol, diethyl ether, a mixture of diethyl ether and dimethyl ether, butyl methyl ether, ethylene glycol monomethyl ether, propylene glycol methyl ether, etc. However, considering the contacting characteristics between the silver-containing antibiotic source and the sapphire workpiece, ethylene glycol monomethyl ether, ethanol and propanol are preferred because they have similar surface energy with the sapphire workpiece. If cost and safety are considered, water and ethanol are preferred. In addition, in order to increase stability of metal ions in the silver-containing antibiotic source, additives such as a thickening agent, chelating reagent, pH modifier, etc can be added into the chemical solution to stabilize the ions therein. Referring to FIG. 1B, the chemical solution method further comprises the steps as follows: providing a spin coating apparatus (step S5121) to rotate at the speed of 5 rpm˜30 rpm and the duration is 30 sec to 5 minutes; using the spin coating apparatus to uniformally coat the silver-containing antibiotic source on the surface of the sapphire workpiece for forming an antibiotic film thereon (step S5123); performing a drying procedure to dry the sapphire workpiece (step 5125) at a temperature of 100˜200° C. with a duration of 3˜10 minutes till the solution on the surface is completely volatile; heating the sapphire workpiece at a temperature of 230˜500° C. for a duration of 3˜5 minutes to perform an organic-salt thermal degradation procedure and stabilize the antibiotic film; cooling the sapphire workpiece (step 5127) after the heating step, in which the cooling time can be 3˜5 minutes and the cooling temperature can be room temperature such as 20˜32° C.; repeating the steps many times and then performing an annealing procedure to the sapphire workpiece to crystallize the antibiotic film (step S5129), in which duration of the annealing procedure is 25˜40 minutes.

Referring to FIG. 1A and FIG. 1C, the liquid deposition method (step S512) can be an immersion method (step S5120′) and the silver-containing antibiotic source can comprise the steps of: immersing the sapphire workpiece in the silver-containing antibiotic source, in which the ration of tackifying agent is increased to 3˜5% and the liquid has a temperature of 25˜30° C., and the immersing duration is 30 sec˜3 minutes to deposit the silver-containing antibiotic source on a surface of the sapphire workpiece for forming an antibiotic film (step S5121′); taking the sapphire workpiece from the silver-containing antibiotic source; performing a drying procedure to the sapphire workpiece to dry the sapphire workpiece (step S5123′), in which the temperature is 3˜10 minutes and the temperature is 230˜500° C., and the preferable temperature is 3˜5 minutes; heating the sapphire workpiece to perform an organic-salt thermal degradation procedure and stabilize the antibiotic film; cooling the sapphire workpiece (step S5125′) after the heating procedure; the cooling temperature is room temperature such as 20˜32° C., and the cooling time can be 3˜5 minutes; repeating the steps many times and then performing an annealing procedure to the sapphire workpiece to crystallize the antibiotic film (step S5127′) at temperature of 700˜950° C., in which the duration of the annealing procedure is 25˜40 minutes.

### Third Embodiment

Referring to FIG. 1A and FIG. 1D, the processing procedure of the embodiment can be a coating method (step S52), and the silver-containing antibiotic source can comprise silver particles and a methyl acrylate of the polymer type or epoxy resin, in which it can be used as a coating which can be solidified by a UV light, and the coating method comprises the steps of: coating the silver-containing antibiotic source on the sapphire workpiece to form an antibiotic film on the surface of the sapphire workpiece (step 521); and irradiating a UV light to the sapphire workpiece for the antibiotic film to be solidified and adhered on the surface of the sapphire workpiece (step 523).

### Fourth Embodiment

Referring to FIG. 1A, the processing procedure is an ion exchanging procedure (step S54), in which ion exchanging procedure is used to transform the Al₂O₃ layer on the surface of the sapphire workpiece into a surface including silver particles, silver containing aluminum oxide, silver containing chrome oxide, silver oxide or a mixture thereof. The silver-containing antibiotic source comprises materials selected from the group consisting of silver particles, AgAlO₂, AgCrO₂, Ag₂O, silver salt and a mixture thereof, and materials selected from the group consisting of alkaline earth salt, alkaline metal salt and a mixture thereof, and solvents which can dissolve solutes. The ion exchanging procedure comprises the step of: immersing the sapphire workpiece in the silver-containing antibiotic source (the flow chart is omitted) for a duration of 3 minute to 7 hours, and heating the silver-containing antibiotic source to temperature of 250° C. to 550° C. for the Al₂O₃ layer on and below the surface of the sapphire workpiece to be transformed to an antibiotic layer selected from the group consisting of silver containing aluminum oxide, silver oxide, silver particles and a mixture of at least two of the materials above.

Preferably, the silver salt can be silver acetate, silver nitrate, silver sulfate, silver chloride, etc. However, the disclosure is not limited thereto. For example, the alkaline metal salt can be sodium chloride, sodium oxalate, sodium nitrate, potassium nitrate, potassium chloride, etc or mixture of at least two of the materials above. The alkaline earth salt preferably is calcium chloride, calcium oxalate, magnesium chloride or a mixture of at least two of the materials above. However, the disclosure is not limited thereto. Preferably, the alkaline earth salt and the alkaline metal salt are basic. Therefore, the alkaline earth salt and the alkaline metal salt can be used to provide anions to exchange for the aluminum ions from the sapphire workpiece. Therefore, the silver or the silver ions can enter the Al₂O₃ layer in the sapphire workpiece to replace aluminum ions, and the surface of the sapphire workpiece can be modified to be antibiotic for forming an antibiotic layer or an antibiotic surface of the sapphire workpiece.

### Fifth Embodiment

Referring to FIG. 1A and FIG. 1E, the processing procedure in step S5 can be an ion implanting method (step S54), which mainly implants ionized silver (can be charged or not charged) into the surface of the sapphire workpiece using high voltage pulse for modifying the surface of the sapphire workpiece. The silver-containing antibiotic source comprises material selected from the group consisting of silver particles, silver containing aluminum oxide, silver containing chrome oxide, silver oxide, silver salt and a mixture thereof. The ion implanting method comprises the steps as follows. The silver-containing antibiotic source is ionized in step S541, in which the silver-containing antibiotic source is energized by a high voltage arc and the voltage (absolute value) can be about 1 kV to 10 kV. Therefore, an ionized silver-containing source is obtained. The silver of the silver-containing antibiotic source is in a gaseous and ionized state and can be cations or neutral ions which are not charged. The silver-containing antibiotic source is screened by an acceleration method with an electric field or magnetic field to get silver ions in step S543. The silver ions (the ionized silver-containing antibiotic source) are implanted to the surface of the sapphire workpiece in step S545, in which the duration can be a few microseconds to about 10 μs, or preferably 1 μs to 10 μs, or 1 μs to 15 μs. Therefore, the surface of the sapphire workpiece is modified to a silver containing and antibiotic surface. It is noted that the implanted silver ions or other accompanying ions can modify the surface of the sapphire workpiece to a surface containing residual stress, in addition to modifying the surface of the sapphire workpiece to a silver containing and antibiotic surface, for getting the effect of increasing overall stiffness and strength of the sapphire workpiece. In order to make the surface get the strengthening effect of the sapphire workpiece, the surface of the sapphire workpiece is required to have an ion concentration of 10¹³ ions/cm² to 10¹⁹ ions/cm². Therefore, the modified sapphire workpiece would have the strengthening effect in addition to being antibiotic. Accordingly, the surface of the sapphire workpiece is a surface having residual stress in addition to being modified to be an antibiotic surface. The overall stiffness and strength of the sapphire workpiece are greatly increased.

### Sixth Embodiment

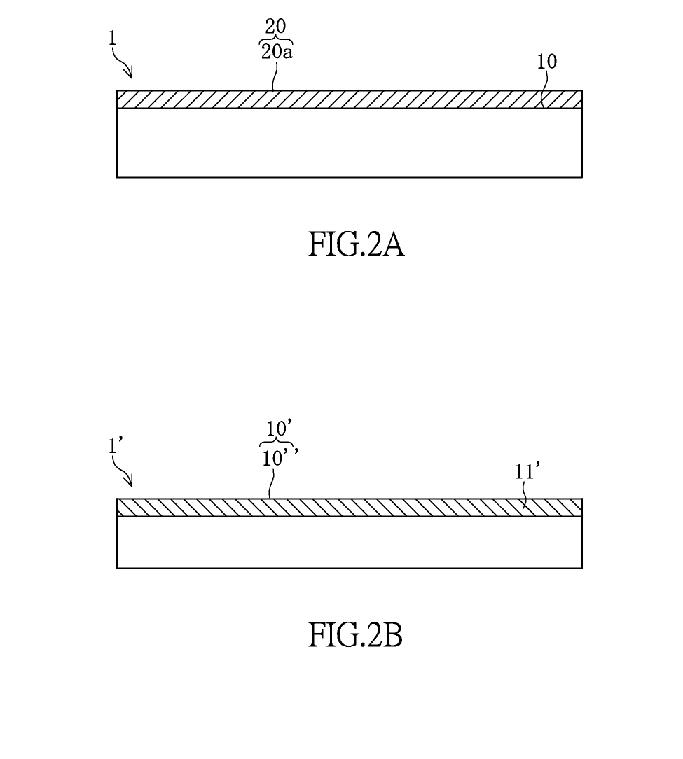

According to the antibiotic treating method of the first and second embodiments, referring to FIG. 2A, the disclosure provides a sapphire 1 comprising a surface 10 and a silver-containing antibiotic source 20, and the silver-containing antibiotic source 20 can form an antibiotic film 20a on a surface 10 of the sapphire 1. Preferably, the silver-containing antibiotic source 20 is a mixture of metal oxide or silver particles, wherein the metal oxide is TiO₂ or Al₂O. The metal oxide is used to transform the antibiotic film to be an antibiotic oxide film and help the antibiotic oxide film to be adhered on the surface of the sapphire. Preferably, the silver-containing antibiotic source 20 is selected from the group consisting of silver containing aluminum oxide (for example AgAlO₂), silver containing chrome oxide (for example AgCrO₂) or a mixture of at least two of the materials above. Similarly, silver containing aluminum oxide or silver containing chrome oxide can be used to transform the antibiotic film to be an antibiotic oxide film and help the antibiotic oxide film to be adhered on the surface 10. Accordingly, TiO₂, Al₂O₂, silver containing aluminum oxide or silver containing chrome oxide can transform the antibiotic film 20a to be an antibiotic oxide film adhered on the surface 10 of the sapphire 1, such that the antibiotic oxide film can be explained as an oxide layer having antibiotic ability.

### Seventh Embodiment

Referring to FIG. 2A, the embodiment is similar to the third embodiment to provide a sapphire 1 comprising a surface 10 and a silver-containing antibiotic source 20 which is formed as an antibiotic film 20a and covers the surface 10 of the sapphire 1. Preferably, the silver-containing antibiotic source 20 can comprise silver particles and a coating curable with a UV light. The coating curable with a UV light can be used to make the silver-containing antibiotic source 20 solidified to be an antibiotic film 20a after being irradiated by a UV light.

### Eighth Embodiment

Referring to FIG. 2B, similar to the fourth and fifth embodiment, the embodiment provides a sapphire 1′ comprising a surface 10′, an oxide 11′ extending into the inner portion of the sapphire from the surface 10′, and a silver-containing antibiotic source. The silver-containing antibiotic source is distributed in the oxide layer 11′ to transform the oxide layer 11′ to be an antibiotic layer and make the surface 10′ be an antibiotic surface 10″. Preferably, the silver-containing antibiotic source is selected from the group consisting of silver particles, AgAlO₂, AgCrO₂ and a mixture of at least two materials.

Therefore, the disclosure according to the embodiments above can solve bacteria proliferation problems for improving personal or public sanitation. Specifically, sapphire is scratch-resistant and thus is suitable to be used for public touch-control devices, such as the touch control screen of a cash dispenser. Furthermore, the disclosure can provide the sapphire to have an antibiotic activity for solving bacterial spreading problems.

The figures and descriptions supra set forth illustrate the preferred embodiments of the instant disclosure; however, the characteristics of the instant disclosure are by no means restricted thereto. All changes, alterations, combinations or modifications conveniently considered by those skilled in the art are deemed to be encompassed within the scope of the instant disclosure delineated by the following claims.

What is claimed is:

1. An antibiotic treating method for a sapphire, comprising
providing a sapphire workpiece;
providing a silver-containing antibiotic source; and
using the silver-containing antibiotic source to perform a processing procedure to the sapphire workpiece for having an antibiotic effect.

2. The antibiotic treating method for a sapphire as recited in claim 1, wherein the processing procedure is a depositing method and the processing procedure further comprises using the depositing method to deposit the silver-containing antibiotic source on and adhered to a surface of the sapphire workpiece.

3. The antibiotic treating method for a sapphire as recited in claim 2, wherein the depositing method is physical vapor deposition, the silver-containing antibiotic source is a mixture of metal oxide and silver particles, wherein the metal oxide is titanium dioxide or aluminum oxide, and the method uses the physical vapor deposition to form an antibiotic film on a surface of the sapphire workpiece.

4. The antibiotic treating method for a sapphire as recited in claim 2, wherein the depositing method is physical vapor deposition, the silver-containing antibiotic source is selected from the group consisting of silver containing aluminum oxide, silver containing chrome oxide and a mixture thereof, and the method uses the physical vapor deposition to form an antibiotic film on a surface of the sapphire workpiece.

5. The antibiotic treating method for a sapphire as recited in claim 2, wherein the depositing method is liquid phase deposition.

6. The antibiotic treating method for a sapphire as recited in claim 5, wherein the liquid phase deposition is a chemical solution method, the silver-containing antibiotic source comprises a source selected from the group consisting of silver containing aluminum oxide, silver containing chrome oxide and a mixture thereof and a solvent, and the chemical solution method comprises:
providing a spin coating tool;
using the spin coating tool to coat the silver-containing antibiotic source on a surface of the sapphire workpiece for forming an antibiotic film thereon;
performing a drying procedure to the sapphire workpiece to dry the sapphire workpiece at a temperature of 100˜200° C., in which the drying procedure has a duration of 3˜5 minutes;
heating the sapphire workpiece at a temperature of 230˜500° C. and with a duration of 3˜5 minutes to perform a thermal degrading procedure and stabilize the antibiotic film, and the sapphire workpiece is cooled for a duration of 3˜5 minutes after the heating step; and
repeating the steps above many times and then performing an annealing procedure to the sapphire workpiece at a temperature of 700˜950° C. and with a duration of 25˜40 minutes to crystallize the antibiotic film.

7. The antibiotic treating method for a sapphire as recited in claim 5, wherein the liquid phase deposition is an immersion method, and the silver-containing antibiotic source comprises a source selected from the group consisting of silver containing aluminum oxide, silver containing chrome oxide and a mixture thereof and a solvent, the immersion method comprises the step of:
immersing the sapphire workpiece in the silver-containing antibiotic source to deposit an antibiotic film thereon, and then taking the sapphire workpiece from the silver-containing antibiotic source;
performing a drying procedure on the sapphire workpiece to dry the sapphire workpiece at a temperature of 100˜200° C. and with a duration of 3˜10 minutes;
heating the sapphire workpiece at a temperature of 230˜500° C. and with a duration of 3˜5 minutes to perform a thermal degrading procedure and stabilize the antibiotic film, and the sapphire workpiece is cooled for a duration of 3˜5 minutes; and
repeating the steps above many times and then performing an annealing procedure to the sapphire workpiece at a temperature of 700˜950° C. and with a duration of 25˜40 minutes to crystallize the antibiotic film.

8. The antibiotic treating method for a sapphire as recited in claim 1, wherein the processing procedure is a coating method, and the silver-containing antibiotic source comprises silver particles and a coating curable with a UV light, the coating method comprises:
coating the silver-containing antibiotic source on the sapphire workpiece to form an antibiotic film; and
irradiating a UV light to the sapphire workpiece to solidify the antibiotic film, and the antibiotic film is adhered to a surface of the substrate.

9. The antibiotic treating method for a sapphire as recited in claim 1, wherein the processing procedure is an ion-exchange procedure, the silver-containing antibiotic source comprises a material selected from the group consisting of silver particles, silver containing aluminum oxide, silver containing chrome oxide, silver oxide, silver salt and a mixture thereof, a material selected from the group consisting of alkaline earth metal salt, alkaline metal salt and a mixture thereof, and a solvent which can dissociate solute, the ion-exchange procedure comprises:
immersing the sapphire workpiece in the silver-containing antibiotic source for a duration of 3 minutes to 7 hours, wherein the silver-containing antibiotic source has a temperature of 250˜550° C. to form an antibiotic film selected from the group consisting of silver containing aluminum oxide, silver oxide, silver particles and a mixture with at least two of them.

10. The antibiotic treating method for a sapphire as recited in claim 1, wherein the processing procedure is an ion implanting method, the silver-containing antibiotic source is selected from the group consisting of silver particles, silver containing aluminum oxide, silver containing chrome oxide, silver oxide, silver salt and a mixture thereof, the ion implanting method comprises:
ionize the silver-containing antibiotic source;
screening silver particles from the silver-containing antibiotic source; and
implanting the ionized silver-containing antibiotic source into an Al₂O₃ layer on a surface of the sapphire workpiece.

11. A sapphire, comprising:
a surface; and
a silver-containing antibiotic source forming an antibiotic film on the cover of the surface.

12. The sapphire as recited in claim 11, wherein the silver-containing antibiotic source is a mixture of metal oxide and silver particle, the metal oxide is titanium dioxide or aluminum oxide, and the metal oxide is used to make the antibiotic film forming an antibiotic oxide film, and help the antibiotic oxide film to be adhered to the surface.

13. The sapphire as recited in claim 11, wherein the silver-containing antibiotic source is selected from the group consisting of silver containing aluminum oxide, silver containing chrome oxide and a mixture of at least two materials thereof, and the silver containing aluminum oxide or the silver containing chrome oxide is used to transform the antibiotic film to an antibiotic oxide film and help the antibiotic oxide film to be adhered on the surface.

14. The sapphire as recited in claim 11, wherein the silver-containing antibiotic source comprises silver particles and a coating which can be solidified by UV light, and a coating which can be solidified by UV light is used for the silver-containing antibiotic source to be formed as the antibiotic film after being irradiated by UV light.

15. A sapphire, comprising:
a surface;
an oxide layer extending from the surface to a portion inside the surface; and
a silver-containing antibiotic source distributed in the oxide layer to transform the oxide layer into an antibiotic film, and make the surface form an antibiotic surface.

16. The sapphire as recited in claim 15, wherein the silver-containing antibiotic source is selected from the group consisting of silver particles, silver containing aluminum oxide, silver containing chrome oxide and a mixture of at least two of the materials above.
